(19) United States
(12) Patent Application Publication
(10) Pub. No.: US 2025/0247949 A1
(43) Pub. Date: Jul. 31, 2025

(54) WEARABLE DEVICE INCLUDING STRUCTURE FOR PREVENTING NOISE CAUSED BY STATIC ELECTRICITY

(71) Applicant: ATsens Co.,Ltd., Gyeonggi-do (KR)

(72) Inventors: Soon Keun PARK, Gyeonggi-do (KR); Seung Bum CHO, Gyeonggi-do (KR); Jong Ook JEONG, Gyeonggi-do (KR)

(73) Assignee: ATsens Co.,Ltd., Gyeonggi-do (KR)

(21) Appl. No.: 19/183,521

(22) Filed: Apr. 18, 2025

Related U.S. Application Data
(63) Continuation-in-part of application No. 17/714,649, filed on Apr. 6, 2022, now Pat. No. 12,303,276.

(30) Foreign Application Priority Data
Jul. 5, 2021 (KR) 10-2021-0087857

(51) Int. Cl. H05K 1/02; G06F 1/16; G06F 1/18

(52) U.S. Cl. CPC H05K 1/0219; G06F 1/163; G06F 1/1656; G06F 1/189; H05K 2201/09227; H05K 2201/09272

(57) ABSTRACT

A wearable device is provided. The wearable device is used by being attached to a user's skin. The wearable device includes a main body unit having a housing and a substrate, the substrate being arranged inside the housing, an electrode unit including a sensing electrode connected to the main body unit, and a patch pad unit including one or more conductive members, the one or more conductive members being configured to electrically connect the electrode unit to the user's skin. The electrode unit includes a shielding layer that is not electrically connected to the main body unit. The shielding layer is conductive with a floating potential.

### CROSS-REFERENCE TO RELATED APPLICATION

This application is a continuation-in-part application of U.S. patent application Ser. No. 17/714,649, filed Apr. 6, 2022, which is based on and claims priority under 35 U.S.C. § 119 to Korean Patent Application No. 10-2021-0087857, filed on Jul. 5, 2021, in the Korean Intellectual Property Office, the disclosures of which are incorporated by reference herein in their entirety.

### BACKGROUND

### 1. Field

The disclosure relates to a wearable device, and more particularly, to a wearable device including a structure for preventing noise from deteriorating a measurement signal due to static electricity.

### 2. Description of the Related Art

A wearable device may be attached to a user's body, such as the user's abdomen, back, shoulder, or arm, to measure biosignals such as electromyography, electrocardiogram, pulse signals related to blood pressure, respiratory signals, or brain waves. For example, a wearable device for measuring an electrocardiogram, whose electrodes are in contact with the user's skin, detects electrical activity in the user's heart, and measures the electrocardiogram. Due to such characteristics, the wearable device should operate while being attached to the user's body for a long time.

Meanwhile, on dry days like in winter, static electricity is easily generated due to friction between clothes and the user's body. In particular, when the user does activities while the wearable device is attached to his or her body, static electricity is inevitably generated due to friction between clothes and the wearable device or the user's body. The generated static electricity generates noise in a measurement signal of the wearable device and thus deteriorates the measurement precision.

The above background is technical information possessed by the inventor to derive the disclosure or obtained during a process of deriving the disclosure, and is not necessarily considered to be known art open to the general public prior to the filing of the disclosure.

The wearable device is attached to the skin at a predetermined location based on the type of signals to be measured to detect electrical signals. To ensure accurate diagnosis, the wearable device must remain attached to the user's body for at least 24 hours and up to 14 days to continuously detect the electrical signals. During prolonged measurement periods, the wearable device may not measure signals when adhesion to the skin is not maintained.

Additionally, when the user is dressed and moves in a state in which the wearable device is attached to the user's body, static electricity generated by a garment and the movement may generate noise into the electrical signals.

To address the disadvantages, there is a growing need for a wearable device that enhances adhesion to the skin and reduces the effects of external environmental factors.

### SUMMARY

The disclosure has been devised to solve the above technical problem and provides a wearable device including a structure for preventing noise caused by a static electricity.

However, such a technical problem is an example, and the objective of disclosure to solve is not limited thereto.

Additional aspects will be set forth in part in the description which follows and, in part, will be apparent from the description, or may be learned by practice of the presented embodiments of the disclosure.

According to an embodiment of the disclosure, a wearable device, which is used by being attached to a user's skin, includes a main body unit including a housing and a substrate, the substrate being arranged inside the housing, an electrode unit including a sensing electrode connected to the main body unit, and a patch pad unit including one or more conductive members, the one or more conductive members being configured to electrically connect the electrode unit to the user's skin. The electrode unit includes a shielding layer not to be electrically connected to the main body unit, the shielding layer being conductive with a floating potential.

According to an embodiment of the disclosure, in the wearable device, the shielding layer may be arranged on an upper surface of the electrode unit to cover an electrode pattern layer.

According to an embodiment of the disclosure, in the wearable device, the shielding layer may include a first shielding region and a second shielding region, the first shielding region being spaced apart from an edge of the main body unit by a certain distance, and the second shielding region extending from both sides of the first shielding region.

According to an embodiment of the disclosure, in the wearable device, when viewed from a top, a connection portion of the sensing electrode and the main body unit may be arranged inside the first shielding region, and the one or more conductive members may be arranged inside the second shielding region.

According to an embodiment of the disclosure, in the wearable device, the second shielding region may have a mesh structure therein.

According to an embodiment of the disclosure, in the wearable device, the shielding layer may be printed on an upper surface of the electrode unit with a conductive ink.

According to an embodiment of the disclosure, in the wearable device, a certain potential may be applied to the shielding layer so that external static electricity does not flow into the main body unit.

According to an embodiment of the disclosure, in the wearable device, the electrode unit may further include an electrode pattern layer that is printed on a rear surface of the electrode unit, is in contact with the user's skin through the one or more conductive members, and is connected to the shielding layer to cause external static electricity to flow into the user's skin.

According to an embodiment of the disclosure, a wearable device, which is used by being attached to a user's skin, includes: a main body unit including a housing and a substrate, the substrate being arranged inside the housing; an electrode unit including a sensing electrode connected to the main body unit; and a patch pad unit including one or more conductive members, the one or more conductive members being configured to electrically connect the electrode unit to the user's skin, wherein the electrode unit includes a conductive shielding layer including an electrode that is not electrically connected to the main body unit and is connected to the user's skin.

To accomplish the above object, according to the present disclosure, there is provided a wearable device including: a main body unit which includes a housing and a processing unit arranged within the housing; and an electrode unit which is electrically connected to the main body unit, includes at least one sensing electrode and electrical circuits for the at least one sensing electrode, and is formed of a conductive member, wherein the electrode unit includes a shielding layer having a predetermined pattern formed in a certain region and a bottom layer getting in contact with a user's skin, and the shielding layer is laminated or coated with a predetermined pattern made of an opaque material to diffuse external noise.

The shielding layer includes a first region having the boundary where the main body unit is positioned and a first pattern, and a second region excluding the first region and having a second pattern.

On the shielding layer, a predetermined pattern is formed in the region where the main body unit is not positioned.

The first pattern formed on the shielding layer is a solid pattern that increases bonding strength with the main body unit.

The second pattern formed on the shielding layer is a mesh pattern that reduces external signals including static electricity caused by a user's clothing.

An electrode that senses electro-physical signals (electrocardiogram, electromyography, electrooculography, and impedance) is arranged in an opening of the bottom layer.

The electrode that detects capacitance is arranged in the opening of the bottom layer.

Through the opening of the bottom layer, the sensing electrodes, an insulator, and an air layer are vertically arranged to electrically sense the distance from the skin and detect distance changes caused by skin movement as capacitance changes caused by breathing activity or heartbeat pulse.

Through the opening of the bottom layer, the sensing electrodes, an insulator, and the skin are vertically arranged to detect whether the wearable device touches the skin.

A symbol is printed on the shielding layer. The symbol includes at least of an device identification, a production code, and a wearing direction.

The electrode unit further includes a base layer, and both the top and bottom surfaces of the base layer is covered by a copper foil conductive layer.

Other aspects, features, and advantages other than those described above will become apparent from the detailed description, claims and drawings for carrying out the following disclosure.

The wearable device according to an embodiment of the present disclosure has a structure that is highly flexible in response to the skin surface, enhancing adhesion and allowing accurate measurement of bio-signals.

In addition, the wearable device includes the shielding layer made of the material and/or structure blocking noise, such as static electricity, generated by the user's clothing, thereby preventing noise during measurement, displaying an identification number or the attachment direction of the wearable device, and displaying diffused reflection or specific symbols.

Other aspects, features, and advantages other than those described above will become apparent from the detailed description, claims and drawings for carrying out the following disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 illustrates a wearable device according to an embodiment of the disclosure;

FIG. 2 illustrates a cross-section of the wearable device taken along a line II-II of FIG. 1;

FIG. 3 is an exploded perspective view of a wearable device according to an embodiment of the disclosure;

FIG. 4 is a top view of an electrode unit;

FIG. 5 illustrates an electrode pattern layer of an electrode unit;

FIG. 6 is a top view of a patch pad unit; and

FIG. 7 illustrates a wearable device according to another embodiment of the disclosure.

FIG. 8A is a front view of the wearable device according to embodiments of the present disclosure.

FIG. 8B is a perspective view of the wearable device according to embodiments of the present disclosure.

FIG. 8C is an exploded view of the wearable device according to embodiments of the present disclosure.

FIG. 9 illustrates a state in which a housing is removed from the wearable device. FIG. 10 illustrates a shielding layer of the wearable device.

FIG. 11A illustrates a bottom layer of the wearable device.

FIG. 11B is an exploded view of a bottom layer with an additional support.

FIG. 11C is another exploded view of a bottom layer with an adhesive layer.

FIG. 12 illustrates a cross-section of the wearable device taken along a line III-III of FIG. 8B;

FIG. 13A is a cross-sectional view of an electrode unit of a wearable device according to various embodiments described herein.

FIG. 13B is a cross-sectional view of another electrode unit of a wearable device according to various embodiments described herein.

FIG. 13C is another cross-sectional view of an electrode unit of a wearable device according to various embodiments described herein.

FIG. 14 is a view illustrating a state in which a wearable device (T1) is attached to a user's body.

FIG. 15 is a view of a network environment where a wearable device (T1) is connected to an external user terminal.

### DETAILED DESCRIPTION

Reference will now be made in detail to embodiments, examples of which are illustrated in the accompanying drawings, wherein like reference numerals refer to like elements throughout. In this regard, the embodiments of the present disclosure may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

The disclosure may have various modifications and various embodiments, and specific embodiments are illustrated in the drawings and are described in detail in the detailed description. However, this is not intended to limit the disclosure to particular embodiments, and it will be understood that all changes, equivalents, and substitutes that do not depart from the spirit and technical scope of the disclosure are encompassed in the disclosure. In the description of the disclosure, even though elements are illustrated in other embodiments, like reference numerals are used to refer to like elements.

Hereinafter, embodiments of the disclosure will be described in detail with reference to the accompanying drawings, and in the following description with reference to the drawings, like reference numerals refer to like elements and redundant descriptions thereof will be omitted.

Although the terms “first,” “second,” etc. may be used to describe various elements, these elements should not be limited by these terms. These terms are only used to distinguish one element from another.

An expression used in the singular encompasses the expression of the plural, unless it has a clearly different meaning in the context.

It will be understood that the terms “comprise,” “comprising,” “include” and/or “including” as used herein specify the presence of stated features or elements but do not preclude the addition of one or more other features or elements.

Sizes of elements in the drawings may be exaggerated or reduced for convenience of explanation. In other words, because sizes and thicknesses of elements in the drawings are arbitrarily illustrated for convenience of explanation, the disclosure is not necessarily limited thereto.

The x-axis, the y-axis and the z-axis are not limited to three axes of the rectangular coordinate system, and may be interpreted in a broader sense. For example, the x axis, the y axis, and the z axis may be perpendicular to one another or may represent different directions that are not perpendicular to one another.

In the case where a certain embodiment may be implemented differently, a specific process order may be performed in the order different from the described order. As an example, two processes that are successively described may be substantially simultaneously performed or performed in the order opposite to the order described.

The terms used herein are only used to describe particular embodiments and are not intended to limit the scope of the disclosure. It will be understood that the terms “comprise,” “comprising,” “include” and/or “including” as used herein specify the presence of stated features, numbers, steps, operations, elements, parts, and combinations thereof, but do not preclude in advance the presence or addition of one or more other features, numbers, steps, operations, elements, parts, combinations thereof.

A wearable device may be attached to a user's body, such as the user's abdomen, back, shoulder, or arm, to measure bio-signals such as electromyography, electrocardiogram, electrooculography, electroencephalography (EEG), pulse signals related to blood pressure, respiratory signals, or brain waves. Electroencephalography (EEG) records brain's electrical activity, and the wearable device for measuring electroencephalography can be attached to the user's scalp to measure the brainwave activity. Electromyography (EMG) records the electrical activity of muscles and is used to analyze muscle function, health status, or interactions between nerves and muscles. The wearable device for measuring electromyography is attached to the skin surface to detect the electrical activity in the muscles.

The wearable device for measuring electrocardiogram (ECG) is attached to the user's body so that electrodes of the wearable device are in contact with the skin, thereby detecting the electrical activity in the heart and measuring the electrocardiogram. Electrooculography (EOG) records electrical signals related to eyes to measure eye movements and can be obtained by measuring the potential difference between the cornea and the retina. The wearable device for measuring electrooculography is attached near each eye to detect electrical signals, calculate the potential difference, and measure electrooculography.

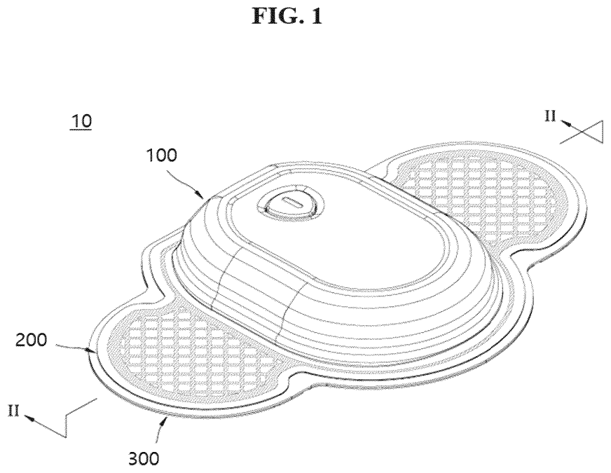

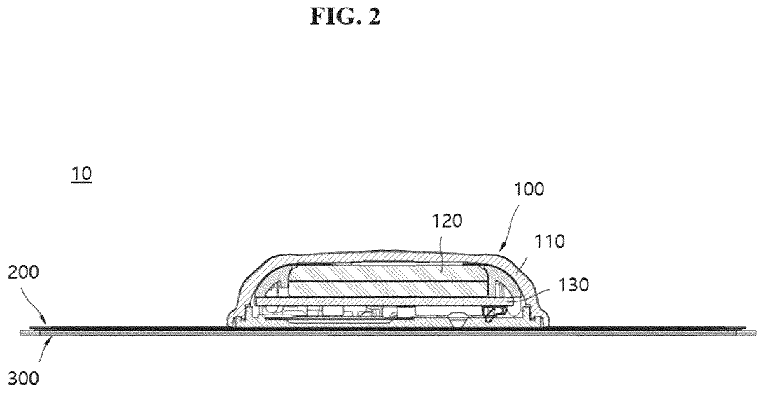

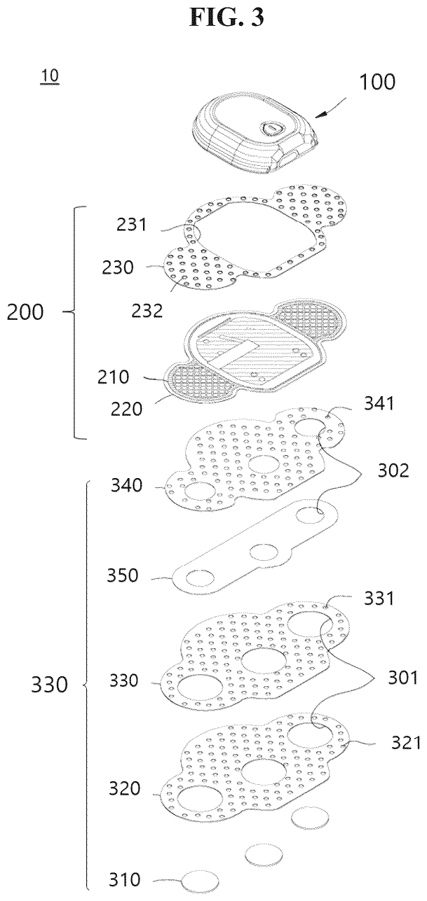

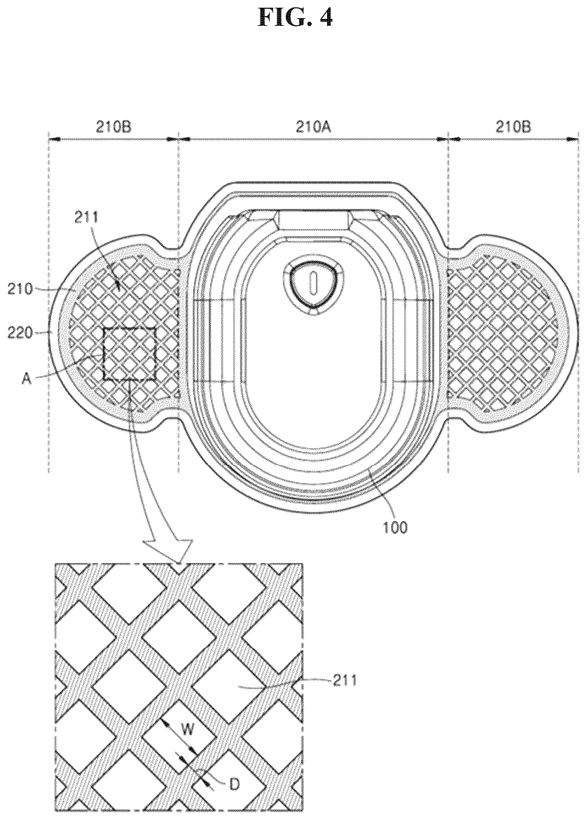

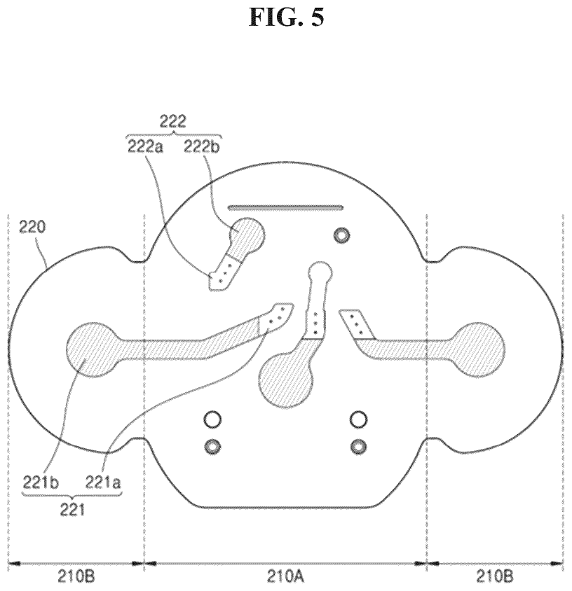

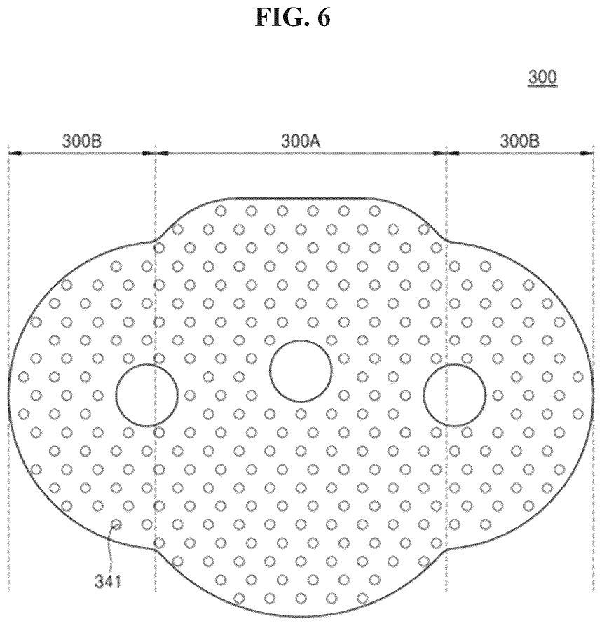

FIG. 1 illustrates a wearable device 10 according to an embodiment of the disclosure, FIG. 2 illustrates a cross-section of the wearable device 10 taken along a line II-II of FIG. 1, FIG. 3 is an exploded perspective view of the wearable device 10, according to an embodiment of the disclosure, FIG. 4 is a top view of an electrode unit 200, FIG. 5 illustrates an electrode pattern layer 220 of an electrode unit, and FIG. 6 is a top view of a patch pad unit 300.

According to an embodiment of the disclosure, the wearable device 10 may be an electronic device that is used by being attached to a user's back, chest, shoulder, arm, or leg. For example, according to an embodiment of the disclosure, the wearable device 10 is attached to the user's skin and measures a biosignal such as an electrocardiogram (ECG), an electromyogram (EMG), or a blood pressure related signal. In an embodiment, the wearable device 10 may be a device for measuring an ECG by inputting, by the electrode unit 200, a voltage generated along with a heartbeat activity. Alternatively, the wearable device 10 may be a device for measuring an electroencephalogram (EEG) by inputting, by the electrode unit 200, a voltage generated from cranial nerves. Alternatively, the wearable device 10 may be a device for measuring an EMG by inputting, by the electrode unit 200, a voltage generated from a skeletal muscle. Also, the wearable device 10 may be a continuous glucose monitor (CGM) or a transdermal therapeutic device using iontophoresis based on a measured biosignal such as an ECG, an EEG, or an EMG.

In an embodiment, the wearable device 10 may be in a contact switch type using a button or a touch switch type. The wearable device 10 may include a circuit for detecting the button press or detecting the touch of an object.

Referring to FIGS. 1 to 6, according to an embodiment of the disclosure, the wearable device 10 may include a main body unit 100, the electrode unit 200, and the patch pad unit 300.

The main body unit 100 is arranged on one side of the wearable device 10 and may include a housing 110, a battery 120, and a substrate 130. In addition, the main body unit 100 is a component for measuring an ECG while the wearable device 10 is attached to the user's body, and may include a processor, a memory, a display, an indicator, communication unit to external devices, and other support structures. Hereinafter, specific components will be mainly described for convenience of description, but unless otherwise stated, components not described are not omitted or reduced in the wearable device 10.

The housing 110 protects other components of the main body unit 100 from an external shock and prevents an external foreign material from being introduced thereinto. A shape, a size, and a material of the housing 110 are not particularly limited and may be appropriately selected according to the purpose of use of the wearable device 10. In an embodiment, the housing 110 may have a dome shape including an internal space.

A button may be arranged on an upper surface of the housing 110. Although FIG. 1 illustrates that only one power button is arranged on the upper surface of the housing 110, the disclosure is not limited thereto. For example, a plurality of buttons for controlling power of the wearable device 10 and controlling an operation mode of the wearable device 10 may be arranged on the upper surface or a side surface of the housing 110.

The battery 120 and the substrate 130 may be arranged in the internal space of the housing 110. For example, as illustrated in FIG. 2, the substrate 130 may be supported by a support structure arranged in the internal space of the housing 110, and the battery 120 may be arranged on the substrate 130. Also, a signal amplification circuit for the wearable device 10 to operate, a signal processing circuit, a control circuit, a processor, communication unit to external devices, and a memory may be arranged on the substrate 130.

In an embodiment, an antistatic paint may be coated on the inside of the main body unit 100. For example, an antistatic paint is coated or applied to the housing 110, so that external static electricity may be prevented from flowing into the main body unit 100 through the housing 110.

The electrode unit 200 may be arranged on one side of the main body unit 100 and may include a sensing electrode 221 (see FIG. 5) connected to the main body unit 100. For example, the electrode unit 200 may be connected to the substrate 130 of the main body unit 100, and the sensing electrode 221 may measure a potential appearing in relation to an electrogram on the body surface or apply a current to inject an electrolyte drug into the user's body through his or her skin or mucous membrane. Also, the sensing electrode 221 may measure an impedance between electrodes.

In an embodiment, the electrode unit 200 may include a shielding layer 210 and the electrode pattern layer 220. The electrode unit 200 may be implemented as a flexible circuit board (FPCB). The shielding layer 210 and the electrode pattern layer 220 may be implemented as a flexible circuit board (FPCB).

The shielding layer 210 may include a conductive material such as a metal, and may be arranged on an upper surface of the electrode unit 200 to prevent an abnormal potential such as external static electricity from being applied to the sensing electrode 221 and affecting a measurement signal. In an embodiment, the shielding layer 210 may be arranged to cover the electrode pattern layer 220 printed on a rear surface of the electrode unit 200.

In an embodiment, the shielding layer 210 may include a first shielding region 210A and a second shielding region 210B. In more detail, as illustrated in FIGS. 3 and 4, the first shielding region 210A may be arranged at the center of the shielding layer 210 so that the main body unit 100 is arranged inside the first shielding region 210A. Also, when viewed from the top, the first shielding region 210A may be spaced apart from an edge of the main body unit 100 by a certain distance, and the main body unit 100 may be arranged inside the first shielding region 210A. In FIG. 4, the main body unit 100 is located at the center area. But, the main body unit 100 can be located at other area depending upon measuring body location, measuring signal, or industrial purpose.

In an embodiment, when viewed from the top, a connection portion of the sensing electrode 221 and the main body unit 100 may be arranged inside the first shielding region 210A. That is, the first shielding region 210A may cover a first sensing electrode terminal 221a of the sensing electrode 221, which will be described below. Also, the first shielding region 210A may cover at least one of a plurality of conductive members 310.

The second shielding region 210B may extend from both sides of the first shielding region 210A. When viewed from the top, at least one conductive member 310 may be arranged inside the second shielding region 210B. That is, the second shielding region 210B may over at least one of the plurality of conductive members 310.

In an embodiment, the shielding layer 210 may be floating relative to the main body unit 100. That is, the shielding layer 210 and the main body unit 100 may maintain a state not electrically connected to each other and may have a floating potential. Accordingly, the influence of external static electricity on the main body unit 100 while flowing through the shielding layer 210 may be minimized. The shielding layer 210 may be divided into one or more regions having different patterns. Through the patterns of the shielding layer 210, the electrode unit 200 implemented as a flexible circuit board (FPCB) can have flexibility. Through the flexibility, the wearable device 10 can bend according to the curve of the body.

In an embodiment, the shielding layer 210 may include a plurality of third ventilation holes 211 arranged in a certain pattern. For example, as illustrated in FIG. 4, when the shielding layer 210 is viewed from the top, the plurality of third ventilation holes 211 may be arranged on both sides of the shielding layer 210. That is, the third ventilation holes 211 may be arranged in the second shielding region 210B.

Accordingly, while the wearable device 10 is attached to the user's body, moisture generated from his or her skin may not flow into the main body unit 100 and may be discharged to the outside through the plurality of third ventilation holes 211.

In an embodiment, a width of a third ventilation hole 211 may be greater than a distance between adjacent third ventilation holes 211. In more detail, as illustrated in FIG. 4, a width W of the third ventilation hole 211 may be greater than a distance D between adjacent third ventilation holes 211.

Accordingly, the width of the third ventilation hole 211 may be sufficiently secured to increase moisture permeability, and static electricity applied from the outside may also flow to the outside through a ground electrode 222 of the electrode pattern layer 220, which will be described below, through a region between the third ventilation holes 211. Therefore, both the moisture permeability and an effect of preventing from external signals may be achieved.

Although FIG. 4 illustrates that the plurality of third ventilation holes 211 form a mesh structure, the disclosure is not limited thereto. For example, the plurality of third ventilation holes 211 may each have a circular shape, a polygonal shape, or a shape in which a straight line and a curved line are mixed, and may have different sizes and shapes.

In an embodiment, the shielding layer 210 may be printed on the upper surface of the electrode unit 200 with an inductive ink. The electrode unit 200 may be implemented as a flexible circuit board (FPCB).

In an embodiment, the shielding layer 210 may be in a state in which a certain potential is applied through a separate circuit separated from the main body unit 100 or the electrode unit 200 to prevent external static electricity from flowing into the main body unit 100.

The electrode pattern layer 220 may be arranged on one surface of the electrode unit 200, for example, on the other surface of the electrode unit 200, which is a surface opposite to the shielding layer 210. For example, as illustrated in FIG. 5, the electrode pattern layer 220 may be printed on the rear surface of the electrode unit 200 and may include a plurality of sensing electrodes 221.

Although FIG. 5 illustrates that three electrodes 221 are respectively arranged at the center and both sides of the electrode pattern layer 220 in a longitudinal direction, four or more sensing electrodes 221 or two or less sensing electrodes 221 may be present, and locations of the sensing electrodes 221 are not particularly limited. However, hereinafter, a case in which the wearable device 10 includes three sensing electrodes 221 will be mainly described for convenience of description.

Each of the sensing electrodes 221 may include a first electrode terminal 221a connected to the main body unit 100 (in more detail, connected to the substrate 130 of the main body unit 100) and a second electrode terminal 221b connected to the conductive member 310 of the patch pad unit 300, which will be described below.

In an embodiment, the first electrode terminal 221a of the sensing electrode 221 may be arranged at the center of the electrode pattern layer 220 in the longitudinal direction, and one second electrode terminal 221b may be arranged at each of the center and both sides of the electrode pattern layer 220.

In an embodiment, the electrode pattern layer 220 is in contact with the user's skin and is connected to the shielding layer 210, so that external static electricity may flow into the user's skin. In more detail, as illustrated in FIG. 5, the electrode pattern layer 220 may further include the ground electrode 222 in addition to the sensing electrodes 221. The ground electrode 222 may be in contact with the user's skin and may include a first ground electrode terminal 222a connected to the shielding layer 210 and a second ground electrode terminal 222b connected to the conductive member 310. Also, the ground electrode 222 may not be electrically connected to the main body unit 100 or the first ground electrode terminal 222a may be omitted.

As described above, the electrode pattern layer 220 is connected to the shielding layer 210 and the user's skin so that the user's skin may be used as a kind of ground. Accordingly, when static electricity is generated, energy of the static electricity transmitted from the shielding layer 210 may be grounded to the user's skin. Also, because the ground electrode 222 is not connected to the main body unit 100, external static electricity may be prevented from flowing into the main body unit 100.

The electrode unit 200 may further include an electrode protection layer 230. In addition to the shielding layer 210, the electrode protection layer 230 may block external static electricity to prevent static electricity from affecting the measurement precision of the wearable device 10. For example, as illustrated in FIG. 2, the electrode protection layer 230 may be arranged on the upper surface of the electrode unit 200, that is, on the shielding layer 210. In another embodiment, the electrode protection layer 230 may be implemented with a predetermined conductive material. The electrode protection layer 230 may be disposed on the upper or lower surface of the electrode pattern layer 220. The electrode protection layer 230 may be implemented to occupy all or part of the electrode portion 200. The electrode protection layer 230 may be covered by the shielding layer 210.

In an embodiment, the electrode unit 200 may include a conductor (e.g., a structure printed with a metal paint or a metal body), and a portion of the electrode unit 200 may not be electrically connected to the main body unit 100.

In an embodiment, the electrode protection layer 230 may have an area greater than those of other components of the electrode unit 200. In more detail, because the electrode protection layer 230 has an area greater than those of the shielding layer 210 and the electrode pattern layer 220, a portion of the wearable device 10 may be in contact with the user's body while the wearable device 10 is attached to the user's body.

Such a configuration may prevent external static electricity from affecting the main body unit 100 and cause static electricity to be applied to the user's body by using the user's body as a kind of ground electrode.

In an embodiment, the electrode protection layer 230 may include, on the inside thereof, a mounting groove 231 corresponding to a shape of the main body unit 100 and may include, on the outside thereof, a plurality of fourth ventilation holes 232 arranged in a certain pattern.

In more detail, as illustrated in FIGS. 1 and 2, when the electrode protection layer 230 includes the mounting groove 231 on the inside thereof and is arranged on the electrode unit 200, the main body unit 100 may be positioned inside the mounting groove 231. The mounting groove 231 may be positioned at the center of the electrode protection layer 230 in a longitudinal direction. Also, the plurality of fourth ventilation holes 232 may be arranged on both sides of the mounting groove 231, respectively.

In an embodiment, the plurality of fourth ventilation holes 232 may be arranged in the same pattern as the plurality of third ventilation holes 211. In this case, the same pattern means that sizes of a plurality of ventilation holes and distances therebetween may be slightly different from each other but shapes of the plurality of ventilation holes are the same as rectangular, square, rhombus, or circular shapes.

In an embodiment, the plurality of fourth ventilation holes 232 may be arranged to correspond to the plurality of third ventilation holes 211. That is, the plurality of fourth ventilation holes 232 may have the same size, shape, and location as the plurality of third ventilation holes 211. Also, the plurality of fourth ventilation holes 232 may have irregular shapes with permeability.

Accordingly, even though moisture is generated because the wearable device 10 is worn for a long time, moisture introduced into the electrode unit 200 through the patch pad unit 300 may be smoothly discharged to the outside through the third ventilation holes 211 and/or the fourth ventilation holes 232.

The patch pad unit 300 may be arranged under the electrode unit 200 and may be in direct contact with the user's skin to inject a drug into the user's skin.

In an embodiment, the patch pad unit 300 may include one or more conductive members 310 for electrically connecting the electrode unit 200 to the user's skin, and may include multiple layers including a plurality of ventilation holes. According to an embodiment, the patch portion (300) may not be provided.

In an embodiment, the patch pad unit 300 may include a main region 300A and a pair of sub-regions 300B extending from both sides of the main region 300A, respectively. For example, as illustrated in FIG. 6, the main region 300A may be arranged at the center of the patch pad unit 300 in a longitudinal direction, and the sub-regions 300B may be arranged on both sides of the main region 300A, respectively.

The conductive members 310 are members in direct contact with the user's skin while the wearable device 10 is attached to the user's skin, and may be electrically connected to the electrode unit 200. For example, each of the conductive members 310 may include a biocompatible material and may be hydrogel.

In an embodiment, the conductive members 310 may be in direct contact with the user's skin while being inserted into the patch pad unit 300 through mounting holes 301 provided in each of the main region 300A and the sub-regions 300B of the patch pad unit 300 by one. The mounting holes 301 may be formed through at least one of a plurality of layers of the patch pad unit 300 in a height direction. For example, the mounting holes 301 may be formed through a first attachment layer 320 and an absorption layer 330 of the patch pad unit 300, which will be described below. In addition, the conductive members 310 may be in contact with the electrode unit 200 while being inserted into the mounting holes 301.

In an embodiment, the conductive members 310 may be in contact with the electrode unit 200 while being inserted into the patch pad unit 300 through contact holes 302 provided in each of the main region 300A and the sub-regions 300B of the patch pad unit 300 by one. The contact holes 302 may be formed through at least one of the plurality of layers of the patch pad unit 300 in the height direction. For example, the contact holes 302 may be formed through a second attachment layer 340 and a current-stopping layer 350 of the patch pad unit 300, which will be described below. In addition, the conductive members 310 may be in contact with the electrode unit 200 through the contact holes 302 while being inserted into the mounting holes 301.

In an embodiment, ventilation holes of the patch pad unit 300 may be arranged in at least one of the main region 300A and the sub-regions 300B except for a region in which the mounting holes 301 and/or the contact holes 302 are formed.

In an embodiment, the patch pad unit 300 may include the first attachment layer 320, the absorption layer 330, the second attachment layer 340, and the current-stopping layer 350.

The first attachment layer 320 is a member in direct contact with the user's skin and may be an adhesive member for fixing the patch pad unit 300 to the user's skin. For example, the first attachment layer 320 is a tape including a biocompatible material and may be a silicon tape.

In an embodiment, the first attachment layer 320 may include a plurality of first ventilation holes 321. For example, as illustrated in FIG. 3, the first ventilation holes 321 may be randomly arranged on the entire surface of the first attachment layer 320 in a remaining region except for the mounting holes 301. Accordingly, sweat generated on the user's skin may be discharged to the outside through the first attachment layer 320 without staying in the first attachment layer 320 for a long time.

The absorption layer 330 may be arranged on the first attachment layer 320 and may include a material capable of retaining moisture so that the sweat generated on the user's skin or external moisture does not flow into the main body unit 100 or the electrode unit 200. In an embodiment, the absorption layer 330 may be a fibrous layer, and more particularly, may include a non-woven fabric and may re-discharge retained moisture.

The second attachment layer 340 is a member for attaching the patch pad unit 300 to the electrode unit 200, may be arranged on the absorption layer 330 to connect the electrode unit 200 to the patch pad unit 300, and may include a plurality of second ventilation holes 341. An adhesive material may be coated on both sides of the second attachment layer 340, and the second attachment layer 340 may be a double-sided tape.

In an embodiment, the plurality of second ventilation holes 341 may be arranged to communicate with the plurality of first ventilation holes 321 in a height direction. That is, the plurality of second ventilation holes 341 may be arranged at positions corresponding to the plurality of first ventilation holes 321. Alternatively, the plurality of second ventilation holes 341 may be arranged in the same pattern as the plurality of first ventilation holes 321. Alternatively, the plurality of second ventilation holes 341 may be arranged with the same size, shape, and number as the plurality of first ventilation holes 321.

The patch pad unit 300 may further include current-stopping layer 350 made of a high resistive material.

As illustrated in FIG. 3, the current-stopping layer 350 may be between the absorption layer 330 and the second attachment layer 340 and may prevent current flowing between other members of the wearable device 10 or prevent fine current application between the wearable device 10 and the user's skin.

In an embodiment, the current-stopping layer 350 may include a moisture-permeable material and may be a moisture-permeable polyurethane tape.

In an embodiment, the current-stopping layer 350 may also include ventilation holes, and the ventilation holes may be arranged to communicate with ventilation holes of the first attachment layer 320, the absorption layer 330, and the second attachment layer 340. For example, the ventilation holes of the current-stopping layer 350 may be arranged with the same number, pattern, and shape as the ventilation holes of the first attachment layer 320, the absorption layer 330, and the second attachment layer 340. Although it has been described that the patch pad unit 300 includes a plurality of layers, the patch pad unit 300 may be simplified by using the same function or different materials.

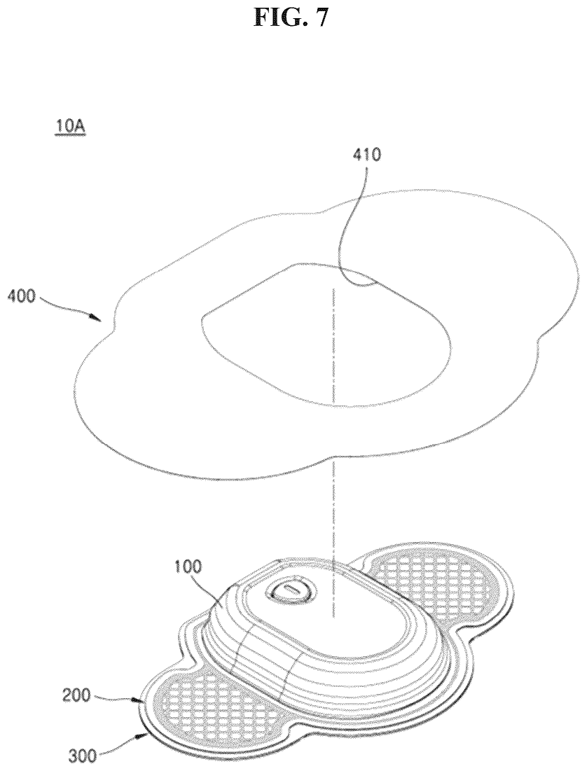

FIG. 7 illustrates a wearable device 10A according to another embodiment of the disclosure. According to the present embodiment, the wearable device 10A may further include a fixing unit 400. The fixing unit 400 includes an accommodation groove 410 in which the main body unit 100 is accommodated, and both side regions of the accommodation groove 410 covers the upper surface of the electrode unit 200.

In one or more embodiments, the fixing unit 400 may have an area greater than those of the electrode unit 200 and/or the patch pad unit 300. In more detail, as illustrated in FIG. 7, at least a portion of the fixing unit 400 may protrude to the outside of the electrode unit 200 and/or the patch pad unit 300 to adhere to the user's skin while the fixing unit 400 is arranged on the electrode unit 200.

In one or more embodiments, the fixing unit 400 may include a moisture-permeable material. For example, the fixing unit 400 may include a material having moisture directionality, such as a moisture-permeable polyurethane tape or Gore-Tex. Also, the fixing unit 400 may include a waterproof material. Accordingly, the fixing unit 400 may prevent external moisture from flowing into the inside of the wearable device 10A (waterproofness) and may discharge internal moisture to the outside (moisture permeability).

Hereinafter, a method of manufacturing a wearable device, according to an embodiment of the disclosure, will be described. According to an embodiment of the disclosure, the method of manufacturing the wearable device may manufacture a wearable device 10 used by being attached to a user's skin, by assembling a patch pad unit 300 by stacking a plurality of layers, and stacking the assembled patch pad unit 300, an electrode unit 200, and a main body unit 100. Also, according to an embodiment of the disclosure, the method of manufacturing the wearable device may form a plurality of ventilation holes in the patch pad unit 300 by blanking the plurality of stacked layers by using a press tool.

First, the patch pad unit 300 is assembled by stacking the plurality of layers. For example, the patch pad unit 300 is assembled by stacking a first attachment layer 320, an absorption layer 330, a second attachment layer 340, and a current-stopping layer 350.

Next, the electrode unit 200 is assembled by assembling and stacking a plurality of members in a similar manner. For example, the electrode unit 200 may be assembled by forming a shielding layer 210 and an electrode pattern layer 220 in the electrode unit 200, and then arranging an electrode protection layer 230 on the shielding layer 210. However, an order of assembling the electrode unit 200 and the patch pad unit 300 is not particularly limited, and the electrode unit 200 may be assembled first or the electrode unit 200 and the patch pad unit 300 may be assembled simultaneously.

Next, ventilation holes are formed in the patch pad unit 300 by performing a blanking process by using the press tool. For example, the plurality of ventilation holes may be formed in the patch pad unit 300 by blanking the patch pad unit 300, in which the plurality of layers, such as the first attachment layer 320, the absorption layer 330, the second attachment layer 340, and the current-stopping layer 350, are stacked, by using the press tool.

Next, the wearable device 10 is manufactured by stacking the blanked patch pad unit 300, the electrode unit 200, and the main body unit 100.

In an embodiment, before the electrode unit 200 is assembled, ventilation holes are formed by blanking the shielding layer 210 and the electrode protection layer 230 by using the press tool, and then, the electrode unit 200 may be assembled. In this case, the shielding layer 210 and the electrode protection layer 230 may be blanked while the shielding layer 210 and the electrode protection layer 230 are stacked, or the shielding layer 210 and the electrode protection layer 230 may be blanked separately.

In another embodiment, when ventilation holes having different shapes and patterns are to be formed in the plurality of layers of the patch pad unit 300, a blanking process may be performed on each member first before the patch pad unit 300 is stacked. That is, a blanking process may be performed by using different press tools for each of the first attachment layer 320, the absorption layer 330, the second attachment layer 340, and the current-stopping layer 350 of the patch pad unit 300. Next, the patch pad unit 300 may be assembled by stacking the first attachment layer 320, the absorption layer 330, the second attachment layer 340, and the current-stopping layer 350.

According to an embodiment of the disclosure, the wearable device has a structure for preventing noise caused by static electricity, the structure preventing external static electricity from affecting a main body unit, and thus, the measurement precision of the wearable device may be prevented from deteriorating due to external static electricity.

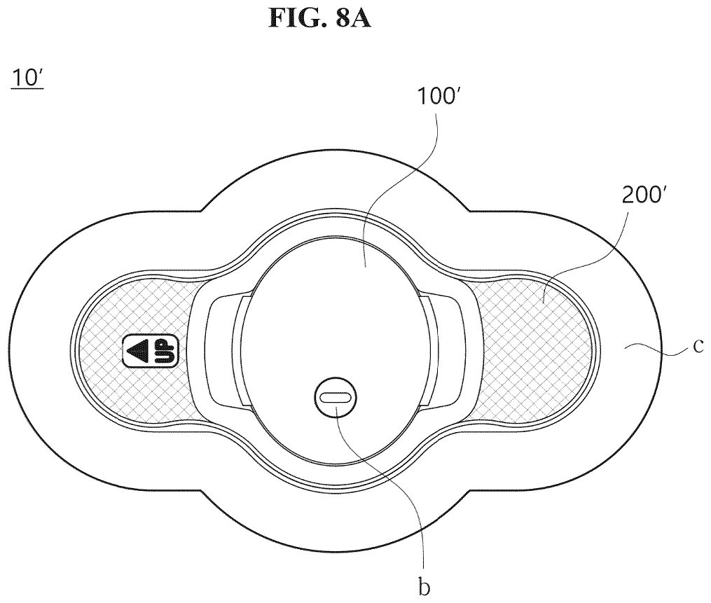

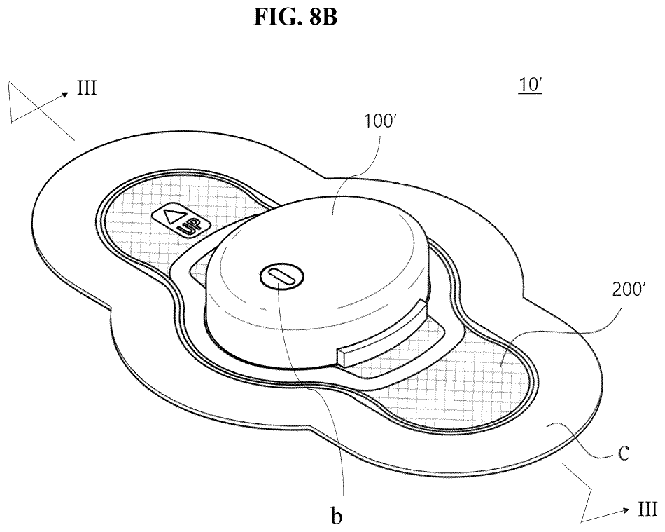

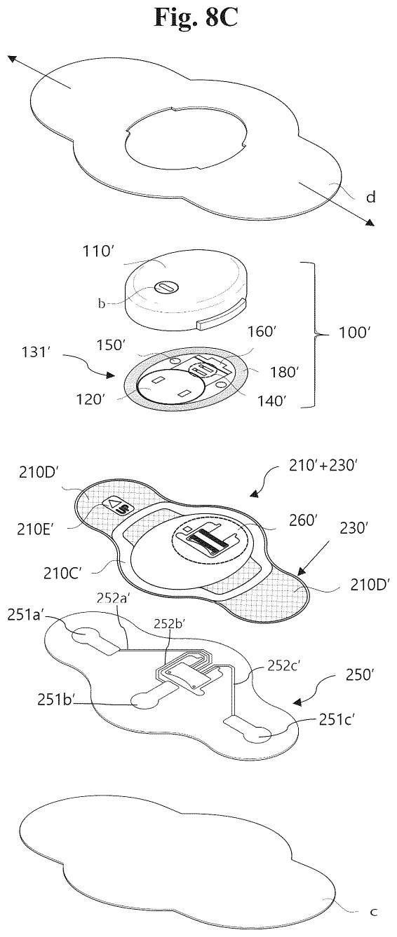

FIG. 8A is a front view of the wearable device 10′ according to embodiments of the present disclosure. FIG. 8B is a perspective view of the wearable device 10′ according to embodiments of the present disclosure, and FIG. 8C is an exploded view of the wearable device 10′ according to embodiments of the present disclosure.

According to an embodiment of the present disclosure, a wearable device 10′ may be an electronic device that is used by being attached to a user's back, chest, shoulder, arm, or leg. For example, according to an embodiment of the disclosure, the wearable device 10′ may be attached to a user's skin to measure bio-signals, such as electroencephalography EEG, electromyography EMG, electrocardiogramalectrooculography EOG, respiration signal, or blood pressure signal. In an embodiment, the wearable device 10′ may detect electrical signals, such as voltage and current impedance (e.g., capacitance and resistance) changes associated with muscle movement, eye movement, brain waves, heartbeat, respiration, or body movement, through sensing electrodes.

The wearable device 10′ may be a device which measures electroencephalogram (EEG) by receiving electrical signals, which are generated when neural signals are transmitted between brain neurons, through sensing electrodes. Alternatively, the wearable device 10′ may be a device which measures electromyogram (EMG) by receiving electrical signals, which are generated from skeletal muscles, through the sensing electrodes. The wearable device 10 may be a device which measures eye position and movement by receiving electrical signals corresponding to the potential difference generated when the eyes move or a device which detects impedance through respiration and body movements.

Additionally, the wearable device 10′ may be a continuous glucose monitor (CGM) utilizing iontophoresis or a transdermal therapeutic device based on measured bio-signals such as electrocardiogram, electroencephalography, electromyography, or electrooculography.

The wearable device 10′ according to embodiments of the present disclosure includes an electrode unit in which a sensor for measuring bio-signals is embedded, and has a pattern provided on the top surface of the electrode unit for diffused reflection. The pattern for diffused reflection may include a mesh, a polygonal shape e.g., hexagonal, or a hole array.

The wearable device 10′ may include a main body unit 100′ and an electrode unit 200′. The electrode unit 200′ may be made of a flexible printed circuit board. The main body unit 100′ is positioned on one side of the wearable device 10′ and, as illustrated in FIG. 8C, may include a housing 110′, a battery 120′, and a processing unit 131′. In addition, the main body unit 100′ may further include components such as a processor, a memory, a display, a communication module, an indicator, and other support structures for measuring electroencephalography, electromyography, electrocardiogram, and electrooculography while the wearable device 10′ is attached to the user's body. Hereinafter, the present disclosure will be focused on specific configurations for the convenience of explanation, but unless otherwise stated, any undescribed components are not excluded from the wearable device 10′.

In FIG. 8C, the housing 110′ protects other components of the main body unit 100′ from external impact and prevents foreign substances from entering. The shape, size, and material of the housing 110′ are not particularly limited, and may be properly selected based on the intended use of the wearable device 10′. In one embodiment, the housing 110′ may have a dome shape with an internal space.

A button b may be positioned on the top surface of the housing 110′. Although FIG. 8A illustrates a single power button on the housing 110, the present disclosure is not limited thereto. For example, a plurality of buttons for controlling power and operation modes of the wearable device 10′ may be placed on the top or side surfaces of the housing 110′.

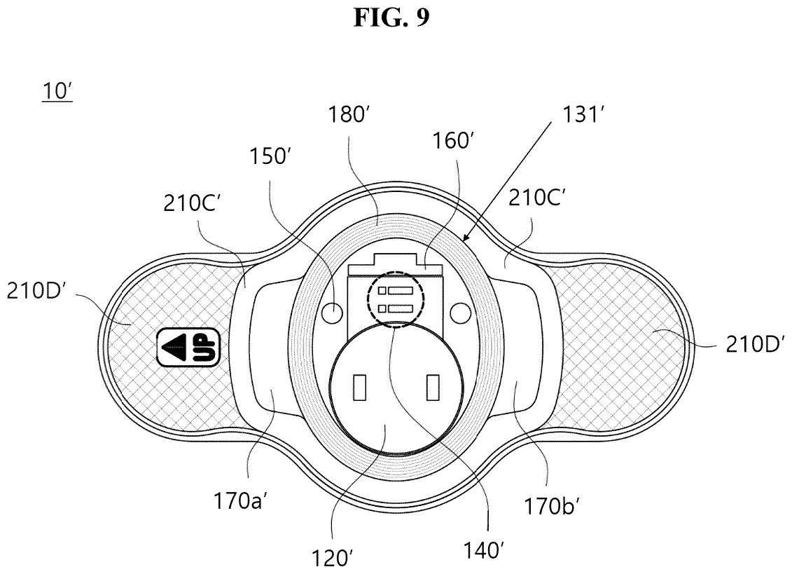

The battery 120′ and the processing unit 131′ may be arranged in the internal space of the housing 110′. For example, the processing unit 131′ illustrated in FIG. 9 may include a signal amplification circuit, a signal processing circuit, a control circuit, a processor, and a memory (not shown in FIG. 9) for operating the wearable device 10′. The processing unit 131′ can acquire and process signals measured from the sensing electrodes. The processing unit 131′ may include a built-in signal processing module. The signal processing module can process signals using algorithms generated from previously measured signals. The signal processing module can determine whether an electrical value of the signal is within a normal range and can transmit and output the determined information to a connected electronic device. The signal processing module can also indicate whether a signal is being measured or not and transmit such information to the connected electronic device.

As illustrated in FIG. 8C, the wearable device 10′ may further include an adhesive layer provided on another side of the electrode unit 200′ and an attachment sheet c to cover the adhesive layer. In other embodiments, the wearable device 10′ may be manufactured without the attachment sheet c. When the wearable device 10′ is in use, the attachment sheet c can be removed.

During use, the attachment sheet c is peeled off, and the wearable device 10′ is attached to the user's body. The attachment sheet c may be made of plastic vinyl material such as polyvinyl chloride but it is not limited thereto. Alternatively, the wearable device 10′ may be manufactured without the attachment sheet c and may be attached to the attachment sheet c after production.

In another embodiment, a waterproof sheet d may cover and protect the electrode unit 200′. The waterproof sheet d may include an accommodation groove that accommodates the main body unit 100′. Both sides of the accommodation groove may cover a portion of the electrode unit 200′. If necessary, the wearable device 10 may be manufactured and used without the waterproof sheet d.

In one embodiment, the waterproof sheet d may have a larger surface area than the electrode unit 200′. As illustrated in FIG. 8C, the waterproof sheet d may be positioned over the electrode unit 200′, with at least a portion of the waterproof sheet protruding outward (shown with arrows) from the electrode unit 200′ to be adhered to the user's skin.

In one embodiment, the waterproof sheet d may be made of a moisture-permeable material. For example, the waterproof sheet d may be a moisture-permeable polyurethane tape or a material with moisture directionality, such as Gore-Tex. Additionally, the waterproof sheet d may be made of a waterproof material. Accordingly, the waterproof sheet d prevents external moisture from entering the wearable device 10′ (waterproofing) and allows internal moisture to be released to the outside (moisture permeability).

Hereinafter, a method for manufacturing a wearable device according to an embodiment of the present disclosure will be described. The method for manufacturing a wearable device according to an embodiment of the present disclosure includes assembling a main body unit 100′ onto a pre-manufactured electrode unit 200′. An attachment sheet c is attached to the assembled main body unit 100′ and one side of the electrode unit 200′ to complete the wearable device 10′. The wearable device 10′ may be delivered to a user as a set that includes a separately manufactured waterproof sheet d. As illustrated in FIGS. 8C and 9, the main body unit 100′ may include an O-ring portion 180′ which is in close contact with the housing 110′ and a connector 140′ to which the electrode unit is adhered. The connector 140′ of the electrode unit may pass through a slit 160′ and be attached to the connector 140′.

The main body unit 100′ may include the O-ring portion 180′ made of an elastic material corresponding to the housing 110′. The O-ring portion 180′ may be composed of materials such as silicone, Ethylene Propylene Diene Monomer (EPDM), Nitrile Butadiene Rubber (NBR), or Viton.

The main body unit 100 may also include coupling portions 170a′ and 170b′. The coupling portions 170a′ and 170b′ coupled with the housing may be fastening clips such as hooks. In an additional embodiment, the main body unit 100′ may further include a temperature sensor 150′ for detecting temperature. The temperature sensor 150′ may detect external temperature.

The electrode unit 200′ as shown in FIGS. 8A-8B may incorporate one or more sensing electrodes and electric circuits, and include a base layer and conductive layers provided on both upper and lower surfaces of the base layer. The base layer is formed as a thin sheet made of materials such as polyimide or polyester, and one of the conductive layers arranged on the upper and lower surfaces may include the sensing electrode and the electric circuit.

The electrode unit 200′ may further include a shielding layer 210′ and a bottom layer 250′. The shielding layer 210′ may be formed by covering a conductive material with a predetermined material. The shielding layer 210′ may be floating relative to the main body unit 100. That is, the shielding layer 210′ and the main body unit 100′ may maintain a state not electrically connected to each other and may have a floating potential.

The shielding layer 210′ may include a region 210C′ where the main body unit 100′ is positioned and a region 210D′ where the main body unit 100′ is not positioned. The region 210D′ where the main body unit 100′ may extend outward in both directions from the main body unit 100′, but it is not limited thereto and may extend in only one direction among left, right, top, and bottom directions.

Preferably, the electrode unit 200′ may have a single sensing electrode in the center and one additional sensing electrode positioned in each direction. However, the locations of the sensing electrodes may vary depending on the placement of the region 210D′ where the main body unit 100′ is not positioned.

The region 210C′ where the main body unit is positioned and the region 210D′ where the main body unit is not positioned may be arranged side by side as shown in FIG. 8C. In another embodiment, the region 210C′ where the main body unit is positioned and the region 210D′ where the main body unit is not positioned may be arranged at a predetermined angle.

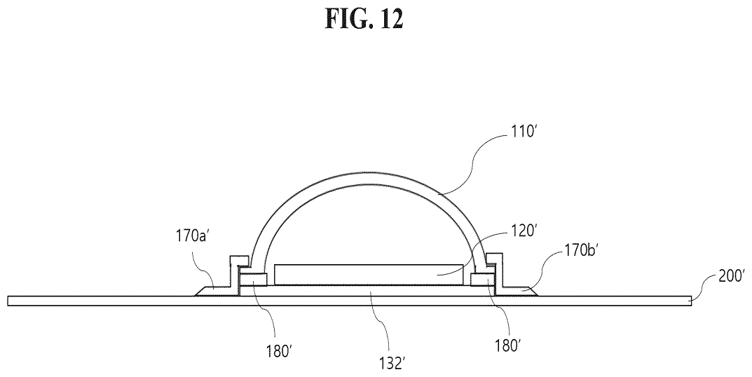

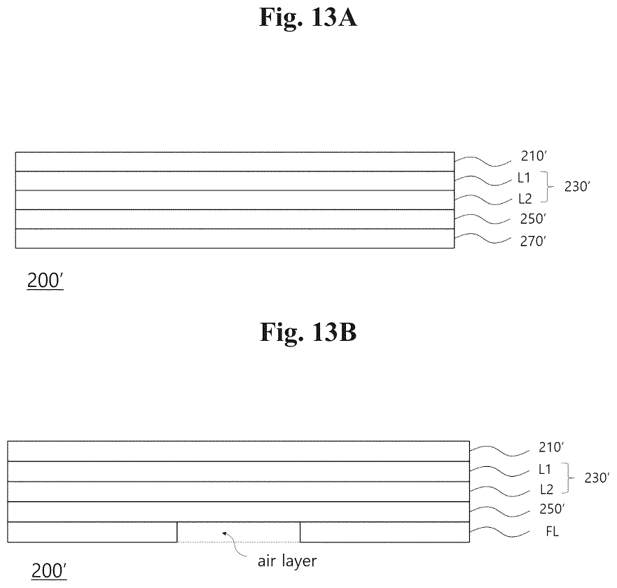

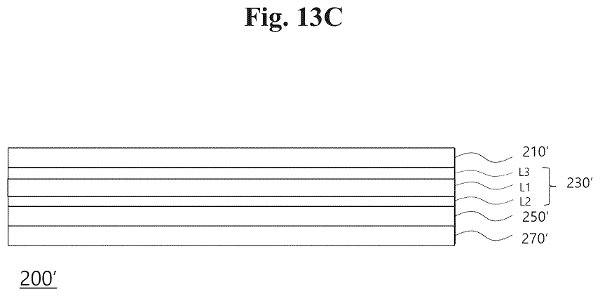

According to embodiments of the present disclosure, the shielding layer 210′ of the electrode unit 200′ is covered with an opaque material to prevent exposure of the sensing electrodes and/or the electric circuits. The shielding layer is laminated or coated with a predetermined pattern made of the opaque material to diffuse electromagnetic interference. FIG. 13A illustrates a film layer L1, and a conductive layer L2 made of a conductive material. The base layer may include L1 and L2. The base layer may include additional layers in addition to layers L1 and L2.

The electrode unit 200′ of the wearable device 10′ may have a base layer 230′ made of polyimide or polyester. The electrode unit 200′ may further include conductive layers containing the sensing electrodes and the electric circuits that transmit electrical signals from the sensing electrodes, and an insulating layer for electrical isolation of the conductive layers from external influences.

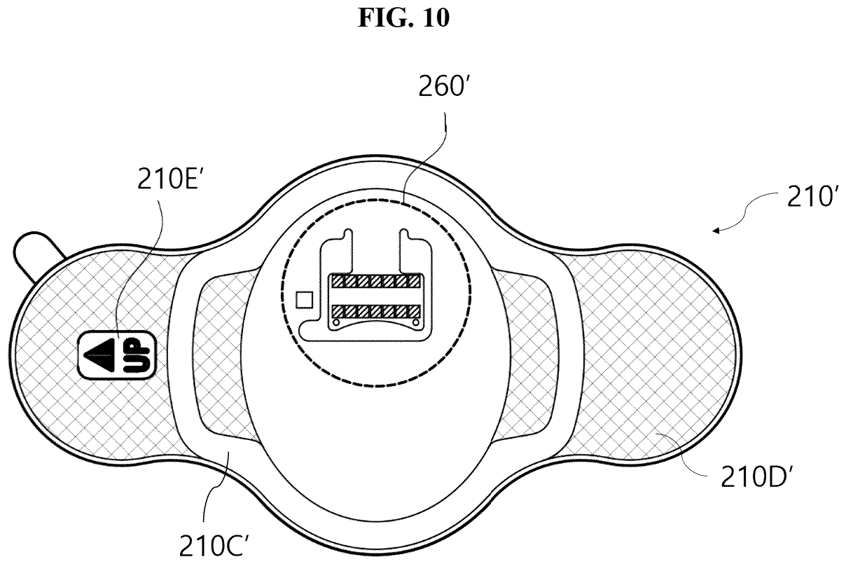

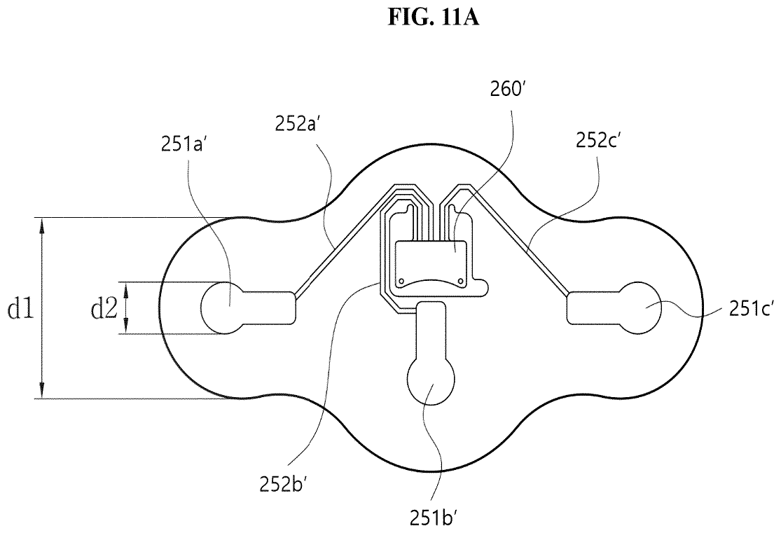

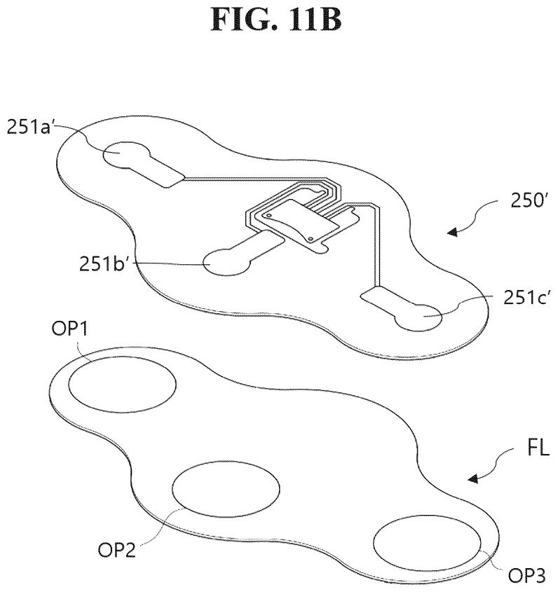

In various embodiments of the present disclosure, additional insulating layers may be formed on the shielding layer 210′ and the bottom layer 250′. The electric circuits of the electrode unit 200′ are connected to the main body unit 100′, performing functions such as receiving or transmitting electrical signals. Additionally, the electrode unit 200′ may include a connector 260′ (see FIG. 11A) to be connected with the processing unit 131′ of the main body unit 100′.

The electrode unit 200′ may include a base layer 230′, a shielding layer 210′, and a bottom layer 250′. The base layer 230′ may comprise a film and a conductive layer made of conductive material. The shielding layer 210′ and the bottom layer 250′ may include the conductive layers made of conductive material and/or insulating layers. The shielding layer 210′ may be formed by coating the conductive layer with a predetermined material. The bottom layer 250′ is positioned on the bottom surface of the base layer 230′, and the shielding layer 210′ and the bottom layer 250′ may be made of different materials. The shielding layer 210′ may be formed of a first material, and the bottom layer 250′ may be formed of a second material.

As illustrated in FIG. 10, the shielding layer 210′ may have a first pattern in the region 210C′ where the main body unit 100′ is positioned to enhance adhesion between the shielding layer and the main body unit arranged on one side of the flexible printed circuit board. The first pattern may be formed to correspond to the contact surface of the main body unit. For example, the first pattern may have a smooth surface matching the contact surface of the main body unit. In another embodiment, the first pattern may be formed to conform to the contact surface of the main body unit. The first pattern may be a solid pattern, but is not limited thereto and may include similar patterns.

In another embodiment, on the shielding layer 210′, the first pattern is formed in a region where the boundary of the main body unit 100′ is located, and a pattern different from the first pattern may be formed in the region where the main body unit 100′ is located.

The shielding layer 210′ may have one or more second patterns formed on the entire or a portion of the region where the main body unit 100′ is not positioned such as the region 210E′. The second pattern may be different from the first pattern and have a predetermined shading effect on the surface. Thus, the shielding layer 210′ increases flexibility in the region where the main body unit 100′ is not positioned, thereby enhancing adhesion to the user's skin. FIG. 9 illustrates an example where the first pattern 210C′ (e.g., a flat pattern) and the second pattern 210D′ are applied. The second pattern 210D′ may be one of a mesh, a polygonal shape (e.g., hexagonal), and a hole array. A hole array is formed on the flexible printed circuit board (FPCB), such that the holes are arranged in a regular pattern on a predetermined region of the FPCB. To enhance the diffused reflection effect, the second patterns may be formed with a predetermined minimum spacing. The minimum spacing value may be, for example, 2 to 3 mm.

Due to the second pattern formed on the shielding layer 210′, the electrode unit can be bent in close contact with the skin. For instance, the second pattern may be a mesh pattern where a predetermined pattern is repeated. The second pattern may include a plurality of mesh patterns. The second pattern formed on the shielding layer 210′ enables the electrode unit 200 to achieve diffused reflection of external stimulation. The second pattern formed on the shielding layer 210′ is covered over the conductive layer, achieving diffused reflection of external stimulation.

The shielding layer 210′ may be covered with an opaque material to prevent visual exposure of the electrodes and electric circuits of the electrode unit. The shielding layer 210′ having the opaque-colored material and the specific pattern allows diffused reflection of external light, and can block external electromagnetic waves, static electricity, and impedance changes caused by external body contact. The shielding layer 210′ is laminated or coated with a predetermined pattern made of an opaque material to diffuse electromagnetic interference.

The shielding layer 210′ may be formed by coating or laminating a first material. Paint and materials of the first material may be covered (laminated or coated) over the conductive layer of the conductive material to form the shielding layer 210′. The thickness of the shielding layer 210′ may vary between the region 210C′ where the main body unit 100′ is positioned and the region 210D′ where the main body unit 100′ is not positioned. For example, the thickness of the region 210C′ where the main body unit 100′ is positioned may be greater than that of the region 210D′ where the main body unit 100′ is not positioned.

Referring to FIG. 10, the shielding layer 210′ may include a label 210E′. The label 210E′ may include an identification number assigned to each wearable device 10′, a designation number for a target where the wearable device 10′ is to be attached. The label 210E′ may further include information related to an attachment direction (wearing direction). The shielding layer 210′ may include at least of specific symbols, device identification information, and directional information.

Referring to FIG. 11A, the bottom layer 250′ is positioned in a direction that the electrode unit 200′ is attached to the skin and may be formed with a second material coating. While the shielding layer 210′ is formed of the first material, the bottom layer 250′ is formed of the second material. The second material may be transparent, unlike the first material, but it is not limited thereto and may also be made of an opaque material. The bottom layer 250′ may be formed from an electrically insulating material. Unlike the shielding layer 210′, the entire bottom layer 250′ may be formed with a single pattern. The bottom layer 250′ with the single pattern can enhance adhesion to the user's skin.

FIG. 11A is a rear view of the electrode unit 200′ of the wearable device. The bottom layer 250′ has a uniform thickness to enhance contactability with the body. Through the bottom layer 250′, the sensing electrode can detect electrical signals generated by muscle movement, heart activity, eye movement, and brain waves. As illustrated in FIG. 11A, the electrode unit 200′ may include three sensing electrodes 251a′, 251b′, and 251c′. The bottom layer 250′ of the wearable device may be formed from transparent materials, coatings, or substances, allowing visual exposure of the electrodes. Through the bottom layer 250′, the sensing electrodes and the electrical circuits may be exposed visually.

FIG. 11B is an exploded view of a bottom layer with an additional support FL. An additional support FL including one more openings OP1, OP2, OP3 may be arranged on one side of the bottom layer 250′. Due to the additional support, an air layer may be formed between the support and the skin. The openings OP1, OP2, OP3 may be positioned to correspond with the sensing electrodes 251a′, 251b′, and 251c′. When the additional support is present, the sensing electrodes 251a′, 251b′, and 251c′ may detect changes of the air layer as electrical signals.

The sensing electrodes 251a′, 251b′, and 251c′ may be designed to detect electro-physical signals. The sensing electrodes 251a′, 251b′, and 251c′ can detect electrical signals from the body, including the skin, eyes, muscles, and brain waves. The sensing electrodes 251a′, 251b′, and 251c′ can detect changes in the air layer formed between the skin and the sensing electrode as electrical signals. For example, when the user's body is changed depending on the user's breathing or movement, the air layer surrounding the sensing electrode. These changes in the air layer formed on the sensing electrodes 251a′, 251b′, and 251c′ is changed, and the change in the air layer can be detected as variations in electrical signals. The signals detected by the sensing electrodes 251a′, 251b′, and 251c′ may include bio-signals such as electromyography (EMG), electrocardiogram, electrooculography (ECG), electroencephalography (EEG), and impedance. The sensing electrode can also measure capacitance values.

The sensing electrodes 251a′, 251b′, and 251c′ can measure potential differences associated with heartbeat, muscle movement, eye movement, and brain waves on the body surface, or apply current to administer electrolyte-based drugs into the body through the user's skin or mucous membranes. The sensing electrodes 251a′, 251b′, and 251c′ can also be used to measure impedance between the electrodes.

The region where the sensing electrode 251a′ is positioned on the electrode unit 200′ may be smaller than the sensing electrodes 251a′, 251b′, and 251c′. For example, the region d2 where the sensing electrodes 251a′is arranged may be smaller than d1 where the sensing electrodes 251a′, 251b′, and 251c′ are arranged and may be approximately one-third the size of d1. The size of d1 may be twice or three times that of d2, but the present disclosure is not limited thereto and may vary.

FIG. 11C is another exploded view of a bottom layer with an adhesive layer 270′.

As illustrated in FIG. 11C, an adhesive layer 270′ having adhesion may be further provided on one side of the wearable device. The adhesive layer 270′ may be positioned on one side of the bottom layer 250′ and may be composed of silicone-based adhesives, polyacrylate adhesives, hydrogel, or similar materials. The adhesive layer 270′ may be formed to cover all or a portion of the bottom layer 250′.

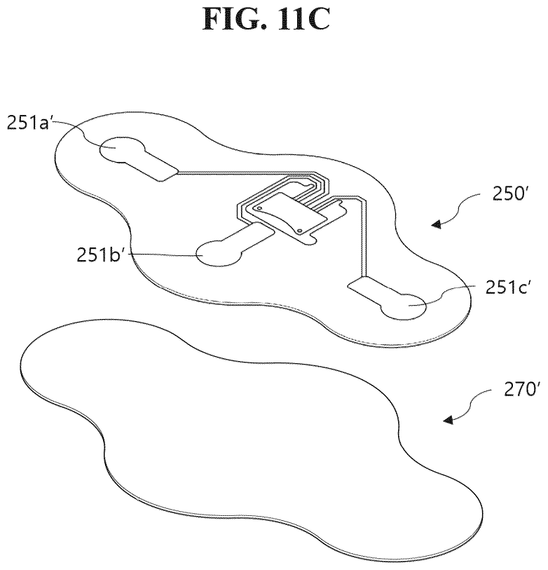

FIG. 12 illustrates a cross-section of the wearable device taken along a line III-III of FIG. 8B. FIG. 12 illustrates the cross-section of the assembled wearable device 10′ manufactured using a method for manufacturing the wearable device 10′. The manufacturing method includes stacking multiple layers to manufacture an electrode unit 200′ as a flexible circuit board, combining the electrode unit 200′ of the manufactured flexible circuit board with a processing unit 131′, and then assembling the housing 110′. More specifically, the electrode unit 200′ of the flexible circuit board and the connector 140′ of the processing unit 131′ are combined, so that the electrode unit 200′ and the processing unit 131′ can be combined. The processing unit 131′ may include the battery 120′, the connector 140′, the slit 160′, the coupling portion 170a′, 170b′, and the O-ring portion 180′, as shown in FIG. 8C. The processing unit 131′ may further include a substrate 132′ on which the connector 140′, the slit 160′, the coupling portion 170a′, 170b′, and the O-ring portion 180′ are arranged, as shown in FIG. 8C and 12. The O-ring portion 180′ may be arranged along an edge of the substrate 132′. When the housing 110′ is pressed to be arranged onto the O-ring portion 180′, the housing 110′ may be attached to the substrate 132′ by the coupling portion 170a, 170b, as shown in FIG. 12.

FIG. 13A is a cross-sectional view of the electrode unit 200′. As illustrated in FIG. 13A, the base layer 230′ may include a film layer L1, and a conductive layer L2 made of a conductive material, and further include a shielding layer 210′ provided on the upper portion of the film layer and a bottom layer 250′ provided on the lower portion of the film layer. An adhesive layer 270′ may be formed on the lower portion of the bottom layer 250′. The adhesive layer 270′ may be formed on the bottom layer 250′, allowing the device to attach to the user's skin. FIG. 13B is another cross-sectional view of the electrode unit 200′. As illustrated in FIG. 13B, the base layer 230′ of the wearable device 10′ may include the film layer L1 and the conductive layer L2, which includes sensing electrodes and electrical circuits. The electrode unit 200′ may further include a shielding layer 210′ provided on the upper portion of the film layer, a bottom layer 250′ provided on the lower portion of the film layer, and a support member FL provided next to the sensing electrode, such that an air layer is formed below the sensing electrode. The height of the support member FL may preferably be between 1 um and 5 um. The air layer allows the wearable device to be attached to the skin to detect capacitance changes caused by the skin movement between the skin and the electrodes of the flexible printed circuit board, enabling the measurement of respiratory signals.

FIG. 13A illustrates a two-layer film, wherein the thickness of the film layer L1 is preferably 2 um, and the thickness of the conductive layer L2 is also 12 um. The shielding layer 210′ and the bottom layer 250′ may be formed thinner than the film layer L1 and conductive layer L2, for example, around 10 um.

FIG. 13C is another cross-sectional view of the electrode unit 200′. The base layer 230′ of the wearable device 10′ may include the film layer L1 and the conductive layer L2, L3, which includes sensing electrodes and electrical circuits. The conductive layers L2 and L3 may be positioned on opposite sides (i.e., above and below) of the film layer L1. Each of the conductive layers L2 and L3 may be realized in the form of a copper coil.

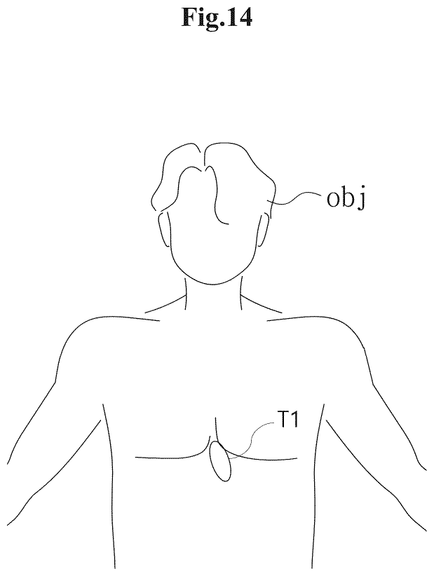

FIG. 14 is a view illustrating the network environment of a wearable device Tl according to the embodiments of the present disclosure. As illustrated in FIG. 14, the wearable device T1 may be mounted non-invasively or invasively near the heart of a subject object (obj) to detect electrocardiogramaignals. The subject obj may refer to a human, an animal, or a body part of the human or animal, such as the chest, scalp, arms, or legs, but is not limited thereto.

The wearable device T1 may also be attached to body areas such as the scalp, and muscle regions, or around the eyes to measure electroencephalography (EEG), electromyography (EMG), and electrooculography (EOG). The wearable device T1 can be attached to a body part depending on the type of bio-signals to be measured, measuring bio-signals. The wearable device T1 can receive the measured electrocardiogram signal and process the electrocardiogram signal using a predetermined method. The wearable device T1 may store and execute a program related to signal processing.

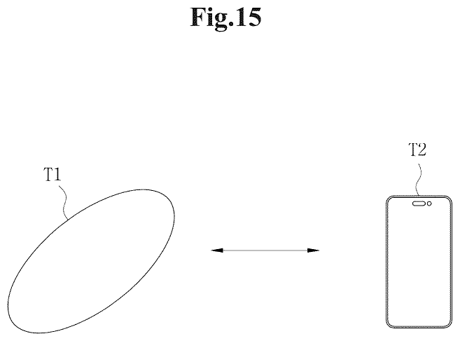

FIG. 15 is a view of a network environment where the wearable device is connected to an external user terminal. The wearable device T1 may transmit and receive data with a user terminal T2 using a communication module built into the processing unit. The communication module may include various wireless communication modules, such as a wireless internet module, a short-range communication module, and a mobile communication module.

The wireless internet module means a module performing communication with external networks based on protocols such as Wireless LAN (WLAN), Wi-Fi, Wireless Broadband (WiBro), Worldwide Interoperability for Microwave Access (WiMAX), and High-Speed Downlink Packet Access (HSDPA).

The short-range communication module means a module for performing communication with nearby external devices using short-range communication methods, such as Bluetooth, Radio Frequency Identification (RFID), Infrared Data Association (IrDA), Ultra Wideband (UWB), and ZigBee. The mobile communication module means a module for performing communication with a mobile communication network following various cellular standards such as 3rd Generation (3G), 3rd Generation Partnership Project (3GPP), and Long-Term Evolution (LTE). However, the communication module is not limited to the technologies, and any other type of communication module capable of transmitting and receiving signals and data with the wearable device T1 may be implemented.

The wearable device T1 may include one or more measurement electrodes for measuring bio-signals such as EEG, EMG, ECG, EOG, respiration signal, and blood glucose levels. The wearable device T1 may store the measured bio-signals in an internal memory. The wearable device T1 can also transmit the bio-signal data to an external device, such as an ECG signal processing unit, through the communication module. Additionally, the wearable device T1 may transmit the measured bio-signals in real time to a user terminal T2.

The user terminal T2 may process the bio-signals measured from the subject obj using methods specific to each bio-signal type. The user terminal T2 can divide the measured bio-signals into predefined signal segments and group or cluster the signal segments. The user terminal T2 may group or cluster each reference signal segment and signal segments with similar patterns based on one or more reference signal segments. The user terminal T2 may also group or cluster the signal segments based on one or more reference values.

An authorized user, such as a medical professional or an analyst, can access the bio-signals through the user terminal T2. The user terminal T2 communicates with the wearable device T1 to receive and display the measured or ongoing bio-signal data.

A patient carrying the user terminal T2 can monitor the bio-signals in real time. The wearable device T1 can transmit a value indicating whether the bio-signal is being properly measured to the user terminal T2. If the bio-signal is not being measured correctly, the wearable device T1 can send a value indicating whether the adhesion of the wearable device T1 to the skin gets weakened, whether displacement of the wearable device may affect on the measurement of the bio-signals, and whether the measured bio-signals are within a normal range. In case of abnormal measurement, the wearable device Tl transmits specific values indicating different causes of measurement failure.

The wearable device T1 may output values of the measurement status through a separate output unit. The wearable device T1 may include an output unit, such as an LED to display the measurement status.

As described above, the disclosure has been described with reference to the embodiment illustrated in the drawings, but this is merely an example. Those of ordinary skill in the art will fully understand that various modifications and other equivalent embodiments can be made from the embodiments. Therefore, the scope of the protection of the technology of the disclosure should be determined by the appended claims.

Specific technical descriptions in the embodiments are embodiments and do not limit the technical scope of the embodiments. In order to concisely and clearly describe the disclosure, descriptions of general techniques and configurations of the related art may be omitted. Also, connections or connection members of lines between elements illustrated in the drawings are examples of functional connections and/or physical or circuit connections, and may be represented by various alternative or additional functional connections, physical connections, or circuit connections in an actual device. In addition, unless specifically stated as “essential” or “importantly”, an element may not be a necessary element for the application of the disclosure.

The term “above” or similar referring expressions used in the description and claims of the disclosure may refer to both the singular and plural expressions unless otherwise specified. Also, when a range is described in the embodiments, it means that embodiments to which individual values belonging to the range are applied are also included (unless otherwise stated), it is the same as each individual value constituting the range is described in the detailed description of the disclosure. Moreover, steps or operations constituting the method according to the embodiments may be performed in an appropriate order, if the order is explicitly stated or unless otherwise stated. The embodiments are not necessarily limited according to the order of the description of the steps or operations. All examples or illustrative terms (e.g., etc.) in the embodiments are merely used to describe the embodiments in detail, and the scope of the embodiments is limited by the examples or illustrative terms unless limited by the claims. In addition, those of ordinary skill in the art will appreciate that various modifications, combinations, and changes can be made in accordance with design conditions and factors within the scope of the appended claims or equivalents thereof.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope included in the following claims.

What is claimed is:

1. A wearable device comprising:
a main body unit which includes a housing and a processing unit arranged within the housing; and
an electrode unit which is electrically connected to the main body unit, including at least one sensing electrode and a plurality of electrical circuits for the at least one sensing electrode, the electrode unit formed of a conductive member,
wherein the electrode unit includes a shielding layer having a predetermined pattern formed in part and a bottom layer contacting a user's skin, and
wherein the shielding layer is laminated or coated with the predetermined pattern made of an opaque material to diffuse electromagnetic interference.

2. The wearable device according to claim 1, wherein the shielding layer includes a first region where the main body unit is positioned and a first pattern is formed, and a second region in which a second pattern different from the first pattern is formed.

3. The wearable device according to claim 1, wherein the predetermined pattern is formed in a region where the main body unit is not positioned.

4. The wearable device according to claim 2, wherein the first pattern formed on the shielding layer is a solid pattern that increases bonding strength with the main body unit.

5. The wearable device according to claim 2, wherein the second pattern formed on the shielding layer is a mesh pattern that reduces static electricity.

6. The wearable device according to claim 1, wherein the at least one sensing electrode that senses electro-physical signals is arranged in line with an opening of the bottom layer.

7. The wearable device according to claim 1, wherein the at least one sensing electrode that detects capacitance is arranged corresponding to an opening of the bottom layer.

8. The wearable device according to claim 6, wherein the at least one sensing electrode, an insulator, and an air layer formed in the opening of the bottom layer are vertically arranged,
the air layer which is a gap with the user's skin, and
the at least one sensing electrode detects a change in a depth of the air layer as a change in capacitance value due to skin movement.

9. The wearable device according to claim 6, wherein the at least one sensing electrode, an insulator, and the user's skin are vertically arranged, and
the at least one sensing electrode detects whether the wearable device touches the user's skin by sensing a capacitance value.

10. The wearable device according to claim 1, wherein a symbol including at least of an device identification, a production code, and a wearing direction is printed on a label in the shielding layer.

11. The wearable device according to claim 1, wherein the electrode unit further includes a base layer, and both a top and bottom surfaces of the base layer are covered by a copper foil conductive layer.
